(19) United States
(12) Patent Application Publication
(10) Pub. No.: US 2013/0136860 A1
(43) Pub. Date: May 30, 2013

(54) METHOD OF FABRICATING A CARBON NANOTUBE ARRAY

(71) Applicants: Weixing Chen, Edmonton (CA); Xinwei Cui, Edmonton (CA)

(72) Inventors: Weixing Chen, Edmonton (CA); Xinwei Cui, Edmonton (CA)

(73) Assignee: THE GOVERNORS OF THE UNIVERSITY OF ALBERTA, Edmonton, AB (CA)

(21) Appl. No.: 13/816,570

(22) PCT Filed: Aug. 12, 2011
(86) PCT No.: PCT/CA2011/050496

§ 371 Date: Feb. 12, 2013

(30) Foreign Application Priority Data
Aug. 12, 2010 (US) 61373174
Aug. 12, 2012 (CA) 2712051

(51) Int. Cl. C23C 16/44; C23C 16/26

(52) U.S. Cl. CPC C23C 16/44; C23C 16/26
USPC 427/249.1

(57) ABSTRACT

A method of fabricating carbon nanotube arrays (CNTA) on an oxide catalyst layer is disclosed. In one embodiment, the oxide catalyst is a metal oxide. The metal oxide may be deposited on a substrate used as a support. The CNTA is grown on the oxide catalyst layer under conditions promoting CNT growth. CNT growth is dependent on temperature, concentration of oxidizing molecules and carbon availability. One embodiment of the method comprises depositing an oxide catalyst layer on the substrate, heating the catalyst layer at certain rates to the target temperatures, adding oxidation molecules for the pretreatment of the oxide catalyst layer, and growing the array on the substrate. The oxide catalyst layer may comprise a group VIII element.

### CROSS-REFERENCE TO RELATED APPLICATIONS

This application claims the benefit of, and incorporates by reference, U.S. provisional patent application Ser. No. 61/373,174 and Canadian patent application serial no. 2,712,051, both filed Aug. 12, 2010.

### BACKGROUND

Carbon nanotube arrays (CNTAs) have properties that are suitable for a variety of practical uses. Methods have been proposed for making CNTAs that involve making the arrays on a metal or metal composite. Further background is contained in Cui et al., “Lengthening and Thickening of Multi-walled Carbon Nanotube Arrays Grown by Chemical Vapor Deposition in the Presence and Absence of Water”, Carbon 48 issue 10 (2010) pp. 2782-2791 (paper A) and in Cui et al., “Effect of Catalyst Particle Interspacing on the Growth of Millimeter-Scale Carbon Nanotube Arrays by Catalytic Chemical Vapor Deposition”, Carbon 47 issue 15 (2009) pp. 3441-3451 (paper B). In paper A and paper B, the authors disclose results of making CNTAs but left out important technical details in the manner of making the CNTAs. The details of making the CNTAs are the subject of this patent disclosure. As additional background, Shanov et al. (US 2008/0095695 A1) discloses a method of forming a CNTA on a substrate comprising depositing a composite catalyst layer on the substrate, oxidizing the composite catalyst layer, reducing the oxidized composite catalyst layer, and growing the array on the composite catalyst layer. Where permitted, papers A and B are incorporated by reference herein. Although the papers A and B list other authors, to the extent the embodiments disclosed and claimed here is disclosed in the papers A and B, the embodiments were conceived solely by the authors Xinwei Cui and Weixing Chen.

### SUMMARY

A method of fabricating carbon nanotube arrays (CNTA) on an oxide catalyst layer is disclosed. In one embodiment, the oxide catalyst is a metal oxide. The metal oxide may be deposited on a substrate used as a support. The CNTA is grown on the oxide catalyst layer under conditions promoting CNT growth. CNT growth is dependent on temperature, concentration of oxidizing molecules and carbon availability. One embodiment of the method comprises depositing an oxide catalyst layer on the substrate, heating the catalyst layer at certain rates to the target temperatures, adding oxidation molecules for the pretreatment of the oxide catalyst layer, and growing the array on the substrate. The oxide catalyst layer may comprise a group VIII element. In another embodiment, carbon nanotube (CNT) wall number and CNTA height can be controlled simultaneously by changing concentration of oxidizing molecules, carbon precursor flow rates, and the pretreatment time for the oxide catalyst layer. CNTA purity can also be controlled by the CNTA growth time. In another embodiment, the lengthening time of CNTA can be substantially increased by increasing H₂ gas flow rate.

In one embodiment, a method of fabricating a carbon nanotube array is disclosed, comprising growing a carbon nanotube array on an oxide catalyst layer under conditions promoting carbon nanotube growth.

In various embodiments, there may be included any one or more of the following features: The method further comprises depositing the oxide catalyst layer on a substrate used as a support prior to growing the carbon nanotube array on the oxide catalyst layer. The oxide catalyst layer comprises a metal oxide. The metal oxide comprises a group VIII element. The method further comprises forming particles of metal oxide catalyst by heating the oxide catalyst layer and adding oxidation molecules for the pretreatment of the oxide catalyst layer prior to growing the CNTA on the oxide catalyst layer. The carbon nanotube (CNT) wall number and CNTA height are controlled simultaneously by changing one or more of the concentration of oxidizing molecules, carbon precursor flow rates, and the pretreatment time for the oxide catalyst layer. The method further comprises controlling CNTA purity by controlling the CNTA growth time. The method further comprises controlling the lengthening time of CNTA by controlling H₂ gas flow rate. The group VIII element comprises at least one of Fe, Co, Ni, Ru, Rh, Pd, Os, Ir, or Pt. The oxide catalyst layer comprises iron oxide. The oxide catalyst layer is 0.5-10 nm thick. The oxide catalyst layer comprises iron oxide.

Further summary may be found in the claims and detailed disclosure.

The reason for the surprising results disclosed in papers A and B has now been found by the authors. Although not explicitly disclosed in the papers, the results were obtained from growing CNTs on an iron oxide catalyst deposited on an alumina intermediate layer.

These and other aspects of the device and method are set out in the claims, which are incorporated here by reference.

### BRIEF DESCRIPTION OF THE FIGURES

Embodiments will now be described with reference to the figures, in which like reference characters denote like elements, by way of example, and in which:

FIG. 1 shows an embodiment of catalyst film layers and preparation procedure;

FIG. 2 shows the catalyst film layers with the catalyst layer broken up into particles (not to scale);

FIG. 3 shows a detailed procedure for CNTA growth by a chemical vapor deposition (CVD) method;

FIG. 4 shows the growth kinetic curve of multi-walled carbon nanotube (MWCNT) arrays grown by water-assisted chemical vapor deposition (WACVD);

FIG. 5 shows a family of histograms of the wall number of MWCNTs grown for different periods, from 5 min to 45 min, by WACVD;

FIG. 6A shows the fitting of the growth kinetic data (dots) of MWCNT arrays grown after 45 min by WACVD to the radioactive decay model (solid line);

FIG. 6B shows a MWCNT with the defined parameters for the dimension of a MWCNT;

FIG. 7 shows the growth kinetic curve of MWCNT arrays grown by CCVD;

FIG. 8A is a plot of MWCNT array height vs. CNT wall number;

FIG. 8B is a plot of MWCNT thickening rate vs. growth time, in CCVD;

FIG. 9 is a plot of CNT wall number as a function of growth time in CCVD; the inset is the enlarged view of the fitting curve in the initial 30 min;

FIG. 10 shows Raman spectra for MWCNT arrays grown for 5 min, 30 min and 120 min by (a) WACVD and (b) CCVD. (c) The growth time dependence of G/D ratio;

FIG. 11 is a schematic diagram of catalyst-induced and gas phase-induced thickening for both tip and root growth modes; \

FIG. 12 shows (a) Growth kinetic curves of CNT arrays grown on 60 min-pretreated Fe oxide (3 nm) and 4 min-pretreated Fe oxide (1 nm) catalyst films, the inset is the corresponding growth rate vs. growth time curves for the two catalyst films; (b) The histograms of the diameter of CNTs grown on the catalyst films in (a); and (c) The histograms of the wall number of CNTs grown on the catalyst films in (a);

FIG. 13 shows (a) a FESEM image of an Fe oxide (1 nm) catalyst film after pretreatment for 4 min, (b) Auger profiles detected from the particles and substrate in the Fe oxide (1 nm) catalyst film in (a), (c) a FESEM image of an Fe oxide (1 nm) catalyst film after pretreatment for 6 min, and (d) an Auger mapping of the Fe oxide (1 nm) catalyst film in (c);

FIG. 14. CNT array height vs. inter-particle spacing, particle size (inset (a)) and particle density (inset (b));

FIG. 15 shows XPS spectra of the as-pretreated catalyst film and the substrate after removal of the grown CNT array;

FIG. 16 shows the wall number of CNTs grown on 60 min-pretreated Fe oxide (3 nm) and 4 min-pretreated Fe oxide (1 nm) catalyst films vs. CNT growth time; and

FIG. 17 shows growth kinetic curves of CNT arrays grown on 4 min-pretreated and 6 min-pretreated Fe oxide (1 nm) catalyst films.

### DETAILED DESCRIPTION

A method of fabricating carbon nanotube arrays (CNTA) on an oxide catalyst layer is disclosed. In one embodiment, the oxide catalyst is a metal oxide. Any typical carbon nanotube catalyst's oxide can be used. Generally, these will be a pure oxide of a group VIII element, including Fe, Co, Ni, or the other group VIII elements of Ru, Rh, Pd, Os, Ir, or Pt. Fe oxide is a preferred catalyst due to its high activity to grow CNTAs. Although results are not provided for other than iron oxide, the utility of other group VIII oxides may be soundly predicted from their similar properties to iron oxide.

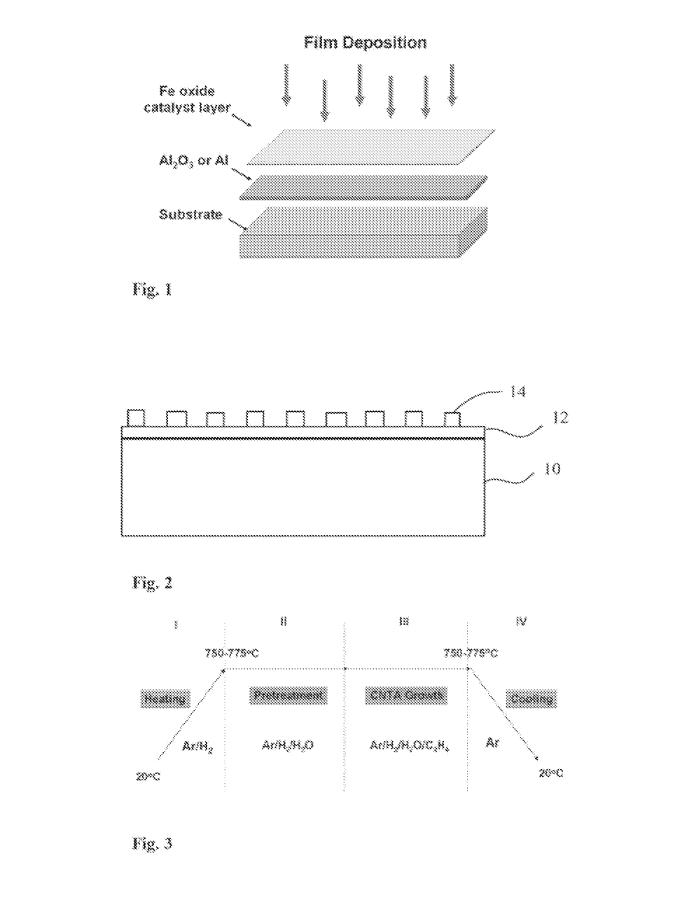

The oxide catalyst may be deposited on a substrate used as a support. The substrate used to support a catalyst layer is not critical. It could be a single crystal silicon wafer (not necessary to be oxidized), quartz, ceramics, glass, and also metals and alloys. Depending on the oxide used as the oxide catalyst, and the nature of the substrate, an intermediate layer may be provided to prevent diffusion of the oxide catalyst into the substrate. Thus, in the case of iron oxide used as the oxide catalyst, an alumina sub-layer on top of the substrate may be important to grow millimeter-long CNTA, although its thickness is not critical. Normally, it could be from around 5 nm to 40 nm, with 10 to 20 nm being preferred. An alternative for the sub-layer is aluminum metallic layer. (See FIG. 1). An oxide catalyst layer may be deposited on the top of the intermediate layer or substrate. The oxide catalyst layer may have a thickness from 0.5 nm to 10 nm, with 1 to 2 nm being preferred for the example of iron oxide.

All kinds of thin film deposition methods (physical and chemical deposition methods) can be used to deposit the oxide catalyst layer. By ways of example and not limitation, sputtering, electron-beam deposition, electro-deposition, electroless deposition, thermal evaporation, and a variety of chemical vapor deposition methods. An example of depositing a Fe oxide catalyst layer is using magnetron sputtering at room temperature under Ar and O₂ flows. The Ar/O₂ flow rate ratio is from 100:1 to 10:1, with between 40:1 and 30:1 being preferred. Direct deposition of a pure oxide catalyst layer, on one hand, saves the complicated steps of depositing composite catalyst layers and being treated by oxidizing and reducing consecutively; on the other hand, it extends the lengthening time of CNTA growth, which improves the controllability and reproducibility of CNTA growth.

For the deposition of 1 to 2 nm Fe catalyst films, it is inevitable to form partially oxidized Fe films if oxygen is present, rather than pure metallic Fe film. Surprisingly, we found that direct deposition of a pure Fe oxide catalyst film significantly affects the stability of the growth process of ultra-long CNTAs, which is superior to the deposited metallic Fe film even being partially oxidized. This was found by an accident, because of the leaking of Ar gas feeding line during sputtering in our lab.

A Fe layer could be formed followed by oxidation of the Fe layer in situ, but this process is hard to control for oxidizing a 1-3 nm deposited Fe layer. For one thing, the catalyst layer may be broken into particles before the total layer is oxidized. This is why Shanov et al. (US 2008/0095695 A1) deposited a composite film and then oxidized the composite film at an intermediate temperature (the second element Gd or La was used to inhibit the diffusion of Fe atoms during oxidation and reduction steps). For another, it's difficult to control the oxygen concentration in the film within a fine range under this circumstance.

The thickness of the Fe layer produced by others is within the range of 0.5 to 10 nm. But their catalyst layer is different from the oxide layer prepared by us. In our case, oxygen is intentionally added with controlled levels.

The oxide catalyst layer may be broken up into particles by heating before nanotubes are grown on the oxide catalyst layer. Referring to FIG. 2 (not to scale), a substrate 10 has an intermediate layer 12 such as for example alumina, and oxide catalyst particles 14 on the intermediate layer. Carbon nanotubes may grow from the oxide catalyst particles.

The CNTA is grown on the oxide catalyst layer under conditions promoting CNT growth. CNT growth is dependent on temperature, concentration of oxidizing molecules and carbon availability. One embodiment of the method comprises depositing an oxide catalyst layer on the substrate, heating the catalyst layer at certain rates to the target temperatures, adding oxidation molecules for the pretreatment of the oxide catalyst layer, and growing the array on the substrate.

For growing CNTs, it is desirable to pump down the CVD furnace reaction chamber to 0.1 to 1 Torr, and purge with Ar gas afterwards. The vacuum level is not critical for the present embodiments, but maintaining vacuum level enhances reproducibility of CNTA growth.

In another embodiment, carbon nanotube (CNT) wall number and CNTA height can be controlled simultaneously by changing concentration of oxidizing molecules, carbon precursor flow rates, and the pretreatment time for the oxide catalyst layer. Oxidizing molecules concentration, carbon precursor flow rates, and pretreatment time or the catalyst layer will change the CNT wall number in the lengthening stage. CNT wall number and CNTA height can be controlled simultaneously.

CNTA purity can also be controlled by the CNTA growth time. Without adding oxidizing molecules in the pretreatment stage, CNTA height could also be adjusted by using different growth time and pretreatment time.

In another embodiment, the lengthening time of CNTA can be substantially increased by increasing H₂ gas flow rate in the CNTA growth stage. H₂ gas flow rate is also important in the heating and pretreatment stages for precise control of particle size of the oxide catalyst. Different H₂ gas flow rates will change the optimum heating rate and pretreatment time for the catalyst layer.

An example of preparing samples by Magnetron sputtering is presented as following: two thin films were sputtered on the piranha cleaned Si wafers, 30 nm-thick Al₂O₃ buffer layer and 1 nm-thick Fe oxide catalyst film. The deposition rate was calibrated by a quartz crystal monitor under the real deposition conditions before any sputtering process. The base pressure was <1.0×10⁻⁷ mTorr. Pulsed-DC magnetron sputtering was used to deposit Al₂O₃ buffer layer at 300° C. with a frequency of 20 kHz and a reverse time of 5 μs. During the deposition, the working pressure was controlled at 5 mTorr with the gas flow rates of Ar (99.999%) and O₂ (99.999%) being 0.98 sccm and 0.14 sccm, respectively. After cooling down to the room temperature, 1 nm-Fe oxide catalyst films were then DC magnetron sputtered on top of the buffer layer at a working pressure of 4 mTorr under the flows of 19 sccm Ar gas and 1.3 sccm O₂ gas (flow rate ratio is 15:1). The power was kept at a very low value, 25 W, ensuring the uniform deposition of Fe oxide catalyst films. This small change of adding 1.3 sccm O₂ gas in the sputtering chamber substantially inhibits the breakage of the catalyst film to nanometer-size catalyst particles during heating step; and thus, stabilizes the growth process of ultra-long CNTAs.

Although the detailed structural change of the catalyst film by adding 1.3 sccm O₂ gas has not been clarified, the beneficial effects brought by this step have been clearly identified. Direct deposition of a pure oxide catalyst layer, on one hand, saves the complicated steps of depositing composite catalyst layers and being treated by oxidizing and reducing consecutively; on the other hand, saves the special setup (e.g. three-zone) of the furnace for the fast-heating step. In other words, this step allows the use of a regular tube furnace and a regular procedure to grow CNTAs. For an example, in the heating step, the heating rate used is 40° C./min from room temperature (25° C.) to one of the target temperatures (775° C.) under Ar (100 sccm) and H₂ (200-400 sccm) gas mixtures. See FIG. 3.

Furthermore, this small change of the sputtering environment, together with the adding of additional oxidizing molecules in the pretreatment step, brings out the phenomena of: 1) super-long lengthening time of ultra-long CNTA growth; 2) large diameter and controlled CNT wall number in CNTAs. This is because this step allows the catalyst film to break into fairly large catalyst particles (10-20 nm), compared with very small catalyst particles (less than 5 nm) prepared by fast-heating treatment.

If we sputter the catalyst film in pure Ar environment, the color of the sputtered layer is brown; however, if we sputter the oxide catalyst film in Ar/O₂ environment, the sputtered layer is transparent (it maintains the color of the Si wafer).

For a specific example of iron oxide catalyst grown on an alumina substrate, a specific set of process conditions may begin as follows. Heat the oxide catalyst layer to the target temperatures for CNTA growth. The target temperatures are from 600° C. to 900° C., with 750° C. to 775° C. being preferred. Heating rate is a variable in these embodiments and it is important for precise control of CNT growth. The oxide catalyst layer does not need a very high heating rate, which saves the special setup (e.g. three-zone) of the furnace.

In a pretreatment step for the oxide catalyst, that is, before CNT growth, add a small amount of oxidizing molecules at the target temperatures to the mixed gases of Ar and H₂. The oxidation molecules could be water, air, ethanol, oxygen-containing aromatics, and the like. These oxidizing molecules substantially extend the range of conditions that can grow CNTAs, and also increase the activity and lifetime of catalyst particles. An example of the pretreatment condition is adding water to Ar (100 sccm) and H₂ (200 sccm) gas mixtures by using 15 sccm Ar gas bubbling through a water bath at the temperature of 23° C., and pretreat the catalyst layer for 10 min. (See FIG. 3). Use of oxide catalyst allows a relatively slow coarsening of particle size, allowing for slow heating and precise control of wall number.

CNTA growth is conducted by adding carbon precursors into the furnace right after the pretreatment stage. An example for carbon precursors is using C₂H₄ gas within the range of 25 to 1000 sccm flow rates. Other carbon precursors can also be employed, such as, methane, acetylene, methanol, ethanol, carbon monoxide, and ferrocene.

Multi-walled carbon nanotube (MWCNT) array growth in these embodiments demonstrates lengthening and thickening stages. In the lengthening stage of WACVD, CNT wall number remains constant and catalysts preserve the activity; while in the thickening stage of WACVD, MWCNTs thicken substantially and the purity deteriorates. Once oxide catalysts have been pre-treated to form relatively small size of particles (as compared with the result using metal or composites), a CNTA may be grown with constant wall number on the oxide catalyst particles formed during pretreatment. CNTA wall number may remain constant during growth. During CNTA growth, the growth rate is controlled by concentration of oxidizing molecules, carbon activity and the pretreatment time.

Single-walled CNTAs (SWCNTAs) can also be grown by the above described procedure except that Fe oxide catalyst layer needs to be directly put into the target temperatures, and pretreated and grown within the environment containing oxidizing molecules, which requires a three-zone furnace.

Paper A—Introduction

A study (disclosed in paper A) was initiated to investigate and understand the growth kinetics of MWCNT arrays in WACVD and conventional chemical vapor deposition (CCVD). The growth kinetics of MWCNT arrays in WACVD and CCVD were investigated by field emission scanning electron microscopy (FESEM), and the CNT diameter and wall number were investigated by high resolution transmission electron microscopy (HRTEM). It was found that the kinetics in both methods demonstrates lengthening and thickening stages. Here, the lengthening is defined as the increase of CNT array height, while the thickening is referred to as the increase of CNT wall number. The detailed analyses of the kinetics in the lengthening stage and thickening stage are presented, and the effect of water has also been elucidated. These findings provide an improved understanding of the growth mechanism and growth kinetics of MWCNT arrays, which may shed light on fabricating MWCNTs with controlled structures and properties. In the growth of carbon nanotube arrays as disclosed here on an oxide catalyst layer, carbon replaces oxygen on the catalyst layer and produces a metal carbide from which the carbon nanotubes grow. After growth of the nanotubes begins, with a given wall number for the nanotube, lengthening proceeds according to known techniques but with better results due to using the oxide catalyst.

Paper A—Experimental Procedure

P-type Si wafers (100) coated with a buffer layer of 30 nm Al₂O₃ film and a catalyst film of 1 nm Fe oxide by DC magnetron sputtering were used as the substrates. A batch of specimens, each with a dimension of 8 mm×8 mm, was cut from a small area on the same substrate sputtered. Catalyst film pretreatment and MWCNT array growth for CCVD are outlined in the discussion of paper B below. In brief, a 1 m-long, single-zone quartz tube furnace with an inner diameter of 5 in was used to grow MWCNT arrays. The chamber was first evacuated to <0.1 Torr. After Ar purging for 1 h, the furnace temperature was ramped up to 750° C. and held for 4 min under 200 sccm Ar and 400 sccm H₂ gas flow. 400 sccm C₂H₄ was then flowed into the system for various periods from 5 min to 2 hrs. For WACVD, another route of Ar gas bubbling through a water bottle (which was kept at 22° C.) with a flow rate of 100 sccm was added during catalyst film pretreatment and MWCNT array growth. As is known in the art, adding appropriate amounts of H₂ and H₂O are considered essential for the catalyst film pretreatment to grow millimeter-long CNT arrays, unless a rapid-heating process was used. The height of MWCNT arrays were characterized by a JSM-6301FXVT™ FESEM. To obtain a statistical distribution of CNT wall number, more than 200 individual CNTs under each growth condition were examined by HRTEM (JEOL™ 2010 operated at 200 kV). Raman spectra were collected in back-scattering geometry with a custom Raman spectrometer, equipped with a 2000 grooves/mm holographic reflection grating, 50 mm f/1.8 Nikon™ camera collection lens, and an Andor™ back-thinned charge-coupled device (CCD) detector cooled to −80° C. Excitation utilized p-polarized light incident at 49° relative to the substrate normal using an Argon ion laser at 514.5 nm (Coherent Innova™ 308). Raman scattered light was collected normal to the sample surface where at least three positions were randomly chosen on each sample.

Paper A—Results and Discussion

Lengthening and Thickening Process in WACVD

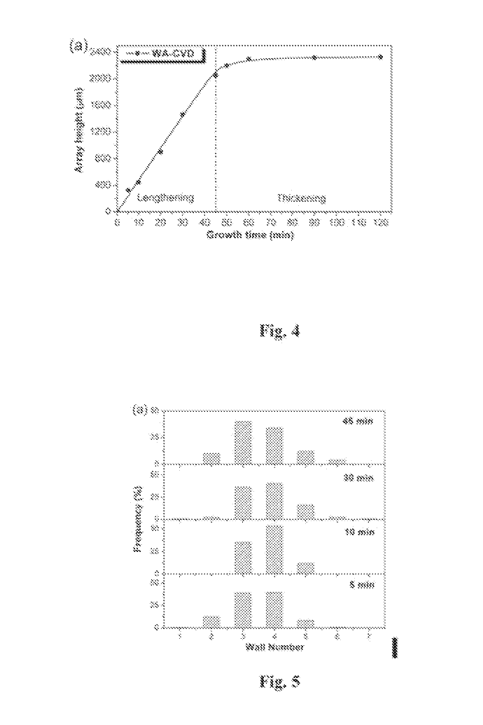

FIG. 4 shows the growth kinetics of MWCNT arrays fabricated through WACVD. The lengthening rate of the array height was found to be constant at 48 μm/min in the initial 45 min. It then gradually decreased over the subsequent 15 min, finally reaching an array height of 2.3 mm. FIGS. 1b-1e of Paper A display the typical HRTEM images of MWCNTs grown for different periods. Little increase of CNT wall number can be observed in the initial 45 min (FIGS. 1b and 1c of paper A), while the increase of CNT wall number is seen to be predominant after 45 min (FIGS. 1d and 1e of paper A). FIG. 4 clearly demonstrates two distinct stages of MWCNT array growth in WACVD: the linear lengthening stage (before 45 min) and the thickening stage (after 45 min). This long linear lengthening stage has not been characterized so far, although it appeared in the growth of MWCNT arrays by WACVD in Schulz's work [Yun Y H, Shanov V, Tu Y, Subramaniam S, Schulz M J. Growth mechanism of long aligned multiwall carbon nanotube arrays by water-assisted chemical vapor deposition. J Phys Chem B 2006; 110(47):23920-5]. It should note that the growth kinetics of MWCNT arrays in WACVD is quite different from that of SWCNT arrays. For the latter case, the lengthening rate decreased exponentially with time and no noticeable linear lengthening stage has been identified [Futaba D N, Hata K, Yamada T, Mizuno K, Yumura M, Iijima S. Kinetics of water-assisted single-walled carbon nanotube synthesis revealed by a time-evolution analysis. Phys Rev Lett 2005; 95(5):056104(4)].

The statistical distribution of wall number of MWCNTs grown for various periods up to 45 min by WACVD is shown in FIG. 5. In the lengthening stage of WACVD, CNT wall number distributes in a very narrow range with triple-walled and four-walled CNTs taking up over 80% of total MWCNTs; and the average wall number, as calculated based on the histograms, remained constant (FIG. S1 of paper A). The substantial increase of CNT wall number after 45 min was also extensively studied by HRTEM, as shown in FIGS. 1 and 2 of paper A. FIGS. 1e and 2b of paper A show a segment of two MWCNTs grown next to each other; thick graphitic layers were found only on the surfaces exposed to the reactive gases, while the wall number didn't increase on the unexposed surfaces. This implies that the outer walls were deposited from the gas phase, probably because the reactive gases cannot diffuse into the small interspacing between the MWCNTs. In addition, it was further revealed in this study that the nucleation sites of graphitic layers on CNT walls from the gas phase appear conical in morphology, as shown in FIG. 2c of paper A. The formation and growth mechanism of conical structure on MWCNTs at high temperatures (>1050° C.) have been investigated by others. The preferential nucleation of graphitic layers at the defects on CNT walls (also shown in FIG. 2c of paper A) could serve as an alternative explanation of forming conical structure at the lower growth temperature (775° C.). Since catalysts are not involved, this thickening process is termed as gas phase-induced thickening in this study. It should be noted that the variation of wall number along the tube axis in FIG. 1d of paper A (an enlarged view is presented in FIG. S2 of paper A) demonstrates the intermediate stage of the gas phase-induced thickening process.

A radioactive decay model was proposed by Hata et al. (referred to above) to explain SWCNT array growth in WACVD, which can be expressed by

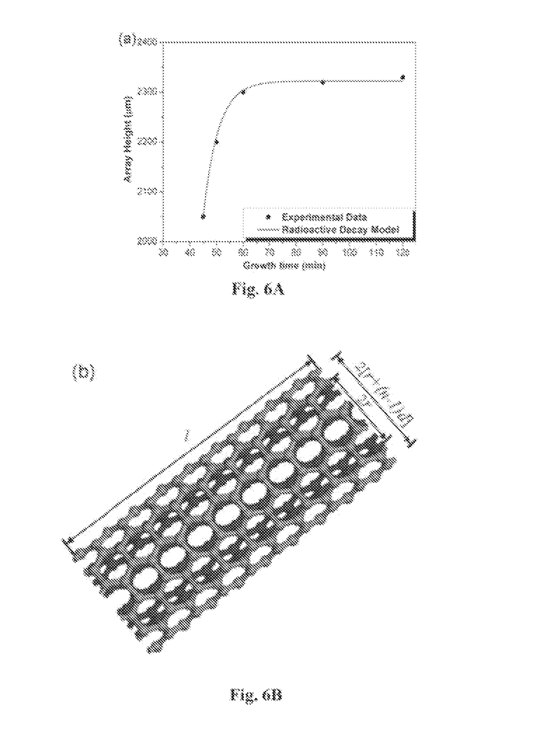

H(t)=ετ₀(1−e^{-t/τ}^{₀}) (1)

where H, β and τ₀ are the height, the initial lengthening rate and the characteristic catalyst lifetime of SWCNT arrays. For MWCNT array growth in WACVD, the entire growth kinetics shown in FIG. 4 could not be fitted by the radioactive decay model to an acceptable agreement, because of a considerable long linear lengthening stage in the initial 45 min. However, fitting the kinetics data for the growth periods from 45 min to 120 min by the radioactive decay model with a predetermined initial lengthening rate of 48 μm/min yielded excellent agreement (R²=0.9962), as shown in FIG. 6A. The fitted characteristic catalyst lifetime is 5.56 min. According to Eq. (1), the product of the initial lengthening rate and the characteristic lifetime when added up to the MWCNT array height at 45 min gives the theoretical maximum height, Hₘₐₓ, which is calculated to be 2317 μm and matches well with the experimentally obtained maximum height of 2330 μm. Since Eq. (1) quantitatively describes the deactivation kinetics for catalyst particles [Futaba D N, Hata K, Yamada T, Mizuno K, Yumura M, Iijima S. Kinetics of water-assisted single-walled carbon nanotube synthesis revealed by a time-evolution analysis. Phys Rev Lett 2005; 95(5):056104(4)], the simulated results reveal that catalyst particles start to deactivate from 45 min. As a result, the simulation further proves that the growth kinetics of MWCNT arrays in WACVD can be divided into two stages, a lengthening stage and a thickening stage. In the lengthening stage, the deactivation of catalyst particles is negligible, while in the thickening stage the deactivation of catalyst particles is evident and follows the radioactive decay model. Interestingly, the constant lengthening rate of the array height (FIG. 4) and the unchanged CNT wall number (FIG. 2A of paper A) in the lengthening stage indicate that the deposition rate of MWCNT graphitic layers from catalysts is invariable. This, in turn, supports that the catalyst activity remains unchanged in the lengthening stage of WACVD.

To quantitatively describe the growth kinetics of MWCNT arrays in the lengthening stage of WACVD, the dimension of a MWCNT is defined in FIG. 6B. Based on FIG. 6B, the area (A) of graphitic walls of a MWCNT is calculated as

$$A = 2 π n ( r + \frac{n - 1}{2} d ) l \qquad ( 2 )$$

where l, r, n, d are the MWCNT length, inner radius, wall number, interspacing of graphitic walls (0.34 nm), respectively. In the case of a fixed wall number, Eq. (3) can be derived from Eq. (2) as

$$\frac{d l}{d t} = \frac{M}{2 π n ( r + \frac{n - 1}{2} d )} \qquad ( 3 )$$

where M is the deposition rate of graphitic layers (M=dA/dt). M is related to catalyst activity if n is the intrinsic wall number (the wall number that is not caused by the gas phase-induced thickening). Assuming that CNT array height can be linearly correlated to the actual CNT length by a coefficient depending on the amplitude of CNT waviness, l could also be considered to be CNT array height. This assumption is reasonable especially for CNT arrays that grow from catalyst patterns with very small inter-particle spacing, in which MWCNTs were observed to be less deviated from the growth direction [as discussed below]. Therefore, Eq. (3) reveals that MWCNT array height increases linearly with growth time when catalyst activity and the intrinsic wall number of MWCNTs remain constant, which quantitatively reflects the situation of MWCNT array growth in the lengthening stage of WACVD (FIG. 4). Thus harvesting MWCNTs with desirable characteristics may be obtained by choosing proper growth conditions. Different linear lengthening stages corresponding to different wall number may be used to produce MWCNT arrays with desirable height and CNT wall number.

It is noted that MWCNTs grown by WACVD in this investigation have a larger inner diameter (7.1 nm) than that in Hata's work (2.8 nm), indicating a larger catalyst particle size for this MWCNT array growth. Smaller catalyst particles are conventionally suggested to have higher activities. It is consistent with the considerable difference in the initial growth rate (IGR) observed in these two studies, 207 nm/min for the supergrowth [Hata] and 48 nm/min for WACVD in this work. This clearly demonstrates the dominant effect of particle size on IGR, although the growth rate could also be affected by catalyst particle interspacing [discussion below] and by catalyst-buffer layer interaction as discussed by others in relation to growth on metal catalysts. Gohier et al. [Futaba D N, Hata K, Yamada T, Mizuno K, Yumura M, Iijima S. Kinetics of water-assisted single-walled carbon nanotube synthesis revealed by a time-evolution analysis. Phys Rev Lett 2005; 95(5):056104(4) also stated that larger catalyst particles have lower chemical reactivity, and hence carbon patches/embryos should be less tightly bound on the surface of the larger particles. As such, the weaker binding of carbon embryos deposited on the surface of large particles could retard the nucleation of graphitic layers on catalyst, which was reported by Feng et al to deactivate catalyst by preventing further absorption of carbon atoms on catalyst. Therefore, the existence of a lengthening stage with unchanged catalyst activity can be expected due to the presence of larger catalyst particles, in comparing with those reported in Hata's work.

Lengthening and Thickening Process in CCVD

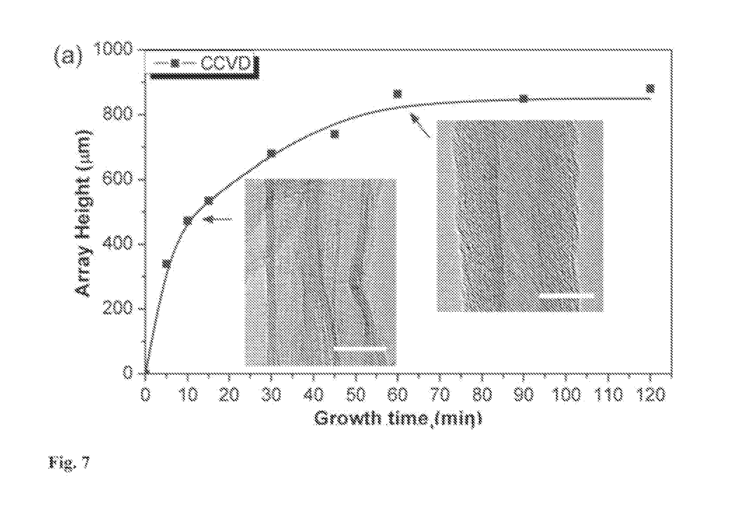

The growth kinetics of MWCNT arrays in CCVD is shown in FIG. 7. Apparently, there is no linear lengthening stage for MWCNT array growth in CCVD as that seen in WACVD. Most CNTs grown for 5 min are double-walled and triple-walled (FIG. 4b of paper A). The CNT wall number increases up to 4-5 walls for the growth period of 15 min (FIG. 4c of paper A), and to 6-8 walls for 30 min (FIG. 4d of paper A). The statistical distribution of wall number of MWCNTs grown for various periods up to 30 min by CCVD is shown in FIG. S3 of paper A. It is interesting that MWCNTs with different wall numbers could be selectively produced in CCVD simply by a control of the growth period in this stage (before 30 min). For longer growth periods, CNT wall number increases rapidly and gas phase-induced thickening becomes prominent, since similar thickening behaviour as shown in FIG. 2b of paper A was easily observed at the growth periods after 60 min in CCVD. In addition, a few MWCNTs grown for 30 min have also been found to undergo nucleation (conical structure) for gas phase-induced thickening (FIG. S4 of paper A) indicating the onset of the gas phase-induced thickening process after 30 min in CCVD.

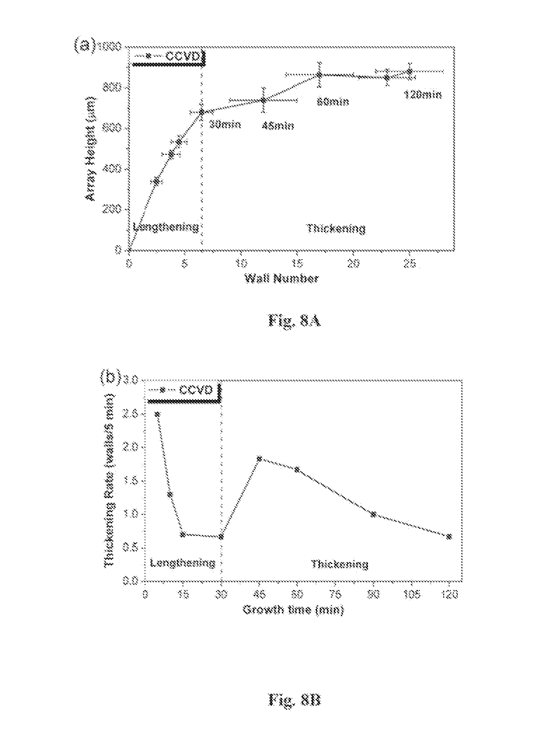

MWCNT array height was plotted as a function of CNT wall number in FIG. 8A. It is evident that in the lengthening stage of CCVD (before 30 min), the lengthening process is predominant, and CNT wall number increases slowly. In the thickening stage of CCVD (after 30 min), the thickening process becomes dominated with little increase of MWCNT array height. FIGS. 7 and 8A indicate that the kinetics of MWCNT array growth in CCVD demonstrates competitive lengthening and thickening processes with the thickening process occurring in CCVD much earlier (after 5 min) than that in WA-CVD (after 45 min).

To further disclose the distinct thickening behaviour in CCVD, the thickening rate is plotted as a function of growth time in FIG. 8B. It is seen in the figure that the thickening rate decreases in the initial 30 min, quickly increases after 30 min and then decreases again. As gas phase-induced thickening becomes predominant after 30 min growth, the increase of thickening rate after 30 min indicates that the accumulation rate of graphitic layers from the gas phase increases with growth time. This is because carbon species previously deposited act as nuclei for further carbon accumulation, which is consistent with the results reported by Hata et al. As MWCNTs grow in wall number, CNT interspacing decreases. This may restrict the flow of reaction gases into the MWCNT arrays and reduce the exposure of MWCNTs to the gas phase. Hence, the thickening rate decreases substantially after 60 min. However, the rapid decrease of the thickening rate in the lengthening stage of CCVD, as seen in FIG. 8B, remains unclear. The nucleation of conical structure by gas phase-induced thickening was not observed in this stage from extensive TEM characterization. It means that the extension of newly nucleated graphitic layers is much faster than continuous nucleation of new graphitic layers at the same location forming the conical structure. More discussion about the distinct thickening behaviour in this stage will be presented later.

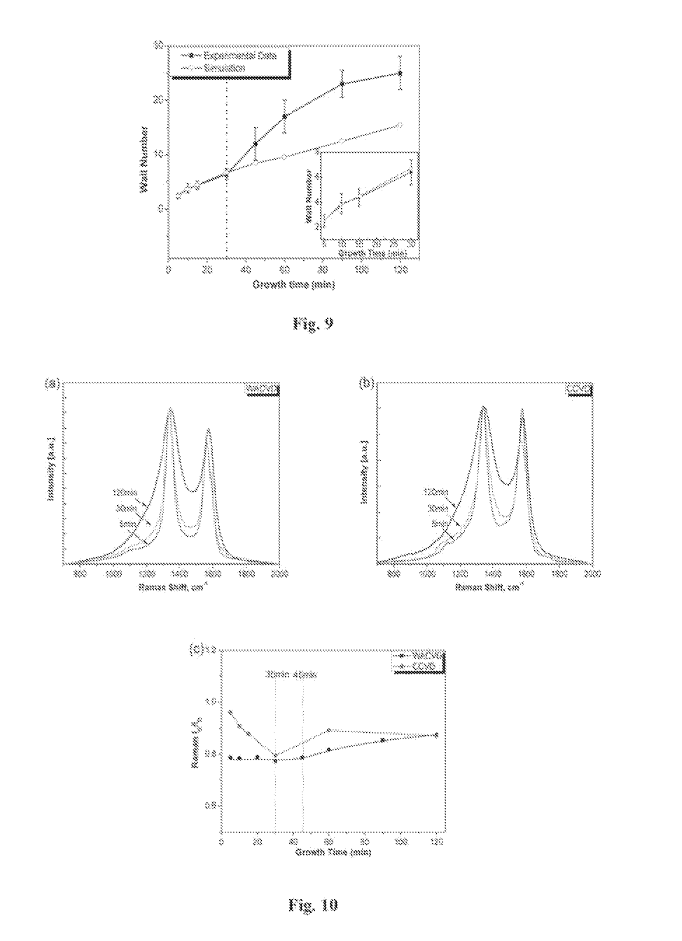

Based on the results shown in FIGS. 7, 5A and 5B, a simulation of CNT wall number vs. growth time was made for MWCNT arrays grown by CCVD. A sheaf of straight lines can be created in FIG. 7 by connecting the origin to the various points of array height. According to Eq. (3), each straight line is characterized by a fixed M value representing the average deposition rate of graphitic layers (dA/dt) up to the growth period, and a fixed n value equal to the CNT wall number of the MWCNT arrays at the growth period. The simulation shown in FIG. 9 was made through the following steps of calculation: first, the initial value of M was obtained from the average growth rate up to 5 min's growth, as shown in FIG. 7, and the average CNT wall number of MWCNT arrays grown for 5 min; this initial M value was then used to predict the CNT wall number corresponding to all subsequent growth periods. FIG. 9 displays that the predicted wall numbers are in a good agreement with the experimental data obtained in the initial 30 min, but appear quite deviated after 30 min. The deviation after 30 min suggests a higher M value in this stage. The increase in M value proves that gas phase-induced thickening become predominant after 30 min, because of the direct deposition of graphitic layers on the CNT walls from the gas phase. On the other hand, M value shows little change for the growth time less than 30 min. The calculation in this stage further reveals that the competitive nature of lengthening and thickening is solely governed by the rate of carbon deposition (constant M); and CNT array height and CNT wall number can be therefore predicted according to Eq. (3). This finding provides us with experimental solutions to fabricate MWCNTs with characteristic structures such as CNT array height and CNT wall number.

Raman Spectroscopy and Thickening Behavior in the Lengthening Stage of CCVD

Raman Spectroscopy is widely used in examining the structural changes of MWCNTs. In this study, first-order Raman Spectroscopy (514.5 nm) was employed on the MWCNT arrays grown for different periods by WACVD and CCVD. The Raman spectra normalized to D peak as shown in (a) and (b) of FIG. 10 demonstrate two Raman bands, G band and D band. G band, at 1570 cm⁻¹, is related to graphite tangential E_{2g} Raman active mode, which is due to the stretching vibrations of sp²-hybridized carbon. D band, 1345 cm⁻¹, is a breathing mode of A_{1g} symmetry, which only becomes active in the presence of disorder, such as heteroatom vacancies, grain boundaries, finite size effects or other effects. Accordingly, the intensity ratio of I_{G}/I_{D} gives the information about the crystallinity of MWCNTs, which was plotted versus growth time in (c) of FIG. 10. As also shown in (c) of FIG. 10, the I_{G}/I_{D} ratio displays a little variation for the MWCNT arrays grown by WACVD. The D peak is substantially broadened by gas phase-induced thickening, as shown in (a) of FIG. 10. The broadening of the D peak is related to a distribution of clusters with different orders and dimensions according to conventional interpretation of Raman spectra, and thus it also indicates the deterioration of the crystallinity of MWCNTs. The broadening of D peak is clearly shown for the MWCNT arrays after 30 min growth by CCVD ((b) of FIG. 10) suggesting that gas phase-induced thickening becomes predominant in this stage, which is consistent with HRTEM observations. Interestingly, (b) and (c) of FIG. 10 also demonstrates that the I_{G}/I_{D} ratio decreases for the MWCNT arrays grown in the initial 30 min of CCVD. It is a different trend from that in WACVD. The decrease of the I_{G}/I_{D} ratio in the lengthening stage of CCVD can be attributed to the distinct thickening process observed in this stage, which will be discussed in detail in the following paragraph.

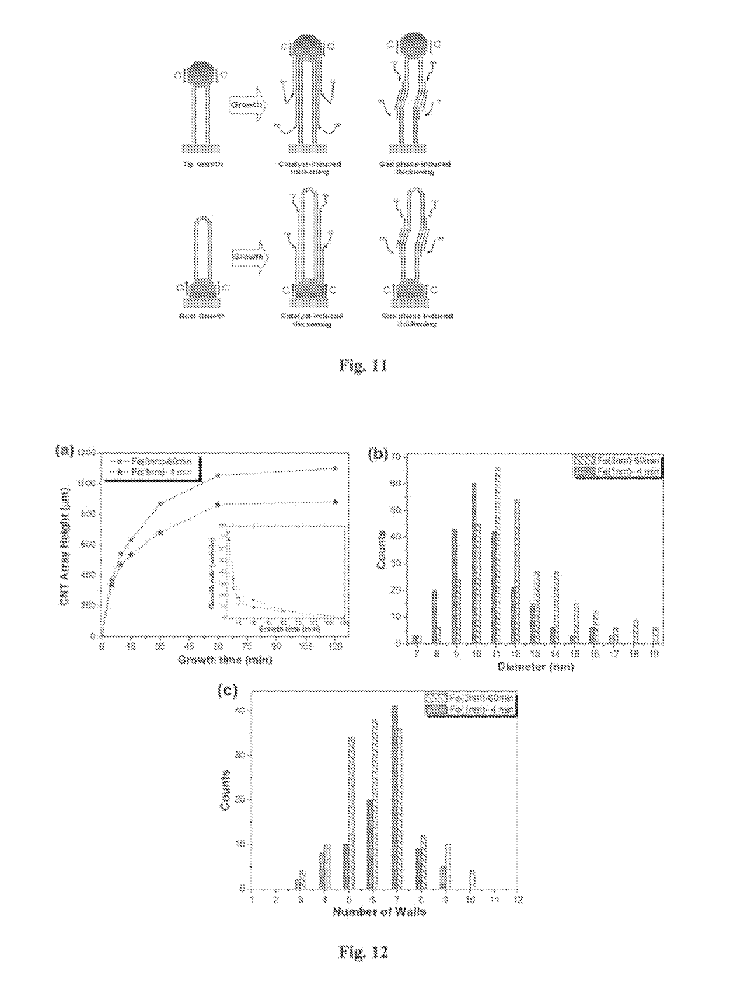

As shown in FIG. 8B, the extension of newly nucleated graphitic layers is much faster than continuous nucleation of new graphitic layers at the same location forming the conical structure in the lengthening stage of CCVD. Thus, the thickening rate in this stage is determined by the nucleation rate of graphitic layers. Amelinckx et al. [Amelinckx S, Zhang X B, Bernaerts D, Zhang X F, Ivanov V, Nagy J B. A formation mechanism for catalytically grown helix-shaped graphite nanotubes. Science 1994; 265(5172):635-9.] proposed that additional graphitic layers would nucleate during MWCNT growth, from the nearest active sites on catalyst or by forming graphene caps around catalyst. This is reasonable because the nucleation rate may be different from the inner walls to the outer walls. Our finding about the nucleation of graphitic layers on CNT walls also suggests their nucleation on the surface of catalyst. It was further proposed that, once new graphitic layers are nucleated on catalyst, they could be extended either by carbon diffusion from catalyst or by carbon deposition directly from the gas phase. It should be noted that, although the thickening in the latter case is caused by carbon deposition from the gas phase, it occurs through a process involving catalyst; and therefore, this thickening process is termed as catalyst-induced thickening in this study. Furthermore, graphitic layers, even if they are nucleated at the defects on CNT walls, could have been joined with graphitic layers nucleated at and grown from catalyst; otherwise, the conical structures should be observed in this stage. The schematic diagram of catalyst-induced thickening and gas phased-induced thickening is shown in FIG. 11.

The nucleation of graphitic layers should be slower on larger catalyst particles, as discussed in WACVD. Therefore, with increasing number of graphene caps around catalyst, catalyst particle size increases and catalyst activity decreases, both of which could reduce the nucleation rate of graphitic layers on catalyst. This explains why the thickening rate decreases with growth time in the lengthening stage of CCVD. In addition, although catalyst-induced thickening couldn't form conical structure, it still induces new defects during the extension of newly nucleated graphitic layers, which decreases the I_{G}/I_{D} ratio in the lengthening stage of CCVD. The constant I_{G}/I_{D} ratio in the lengthening stage of WACVD confirms that no thickening process occurs in this stage, which is also consistent with HRTEM observations.

The Effect of Water

This study investigated the growth kinetics of MWCNT arrays by CVD in the presence and absence of water in the same system. The beneficial effect of adding water in the MWCNT array growth environment is clearly presented. By comparing FIG. 1a of paper A with FIG. 4a of paper A, the duration of the lengthening stage in WACVD is longer (45 min) than that in CCVD (30 min); and the catalysts maintain their activity for a long period, 45 min, in WACVD. These results confirm that water preserves catalyst activity for MWCNT growth, as was known. More importantly, the analyses in this study also prove that water preserves the catalyst activity by significantly inhibiting catalyst-induced and gas phase-induced thickening processes in the lengthening stage of WACVD, in addition to the general belief that water is able to burn out amorphous carbon on catalyst. This might be because water, as a weak oxidizer, increases the activation energy for graphic layers to nucleate on catalyst or at the defects of CNT walls from the gas phase. Furthermore, adding water is known to inhibit Ostwald ripening due to the ability of oxygen and hydroxyl species to reduce diffusion rates of catalyst atoms. Our study also shows that the beneficial effect of water reported here can be achieved only when the catalyst films were pretreated in a Ar and H₂ gas mixture containing small amount of water. It implies that the modification of catalyst particle surface or catalyst pattern in the presence of water is another important factor to inhibit the thickening processes in the lengthening stage of WACVD.

Paper A—Conclusions

By investigating the growth kinetics of MWCNT arrays, it was found that the kinetics demonstrates lengthening and thickening stages in both WACVD and CCVD. In the lengthening stage of WACVD, CNT wall number remains constant and catalysts preserve the activity; while in the thickening stage, MWCNTs thicken substantially by the gas phase-induced thickening process and catalysts deactivate following the radioactive decay model. In CCVD, the lengthening and thickening processes were found to be competitive. Although gas phase-induced thickening also predominates in the thickening stage of CCVD, it was found that catalyst-induced thickening occurs in the lengthening stage of CCVD. Furthermore, water was proved to preserve the catalyst activity by significantly inhibiting catalyst-induced and gas phase-induced thickening processes in WACVD. It is believed that this study, on one hand, confirms the existence of previously proposed radioactive decay model; but more importantly, reveals the unique growth mechanism and growth kinetics of MWCNT arrays in WACVD and CCVD, which are fundamentally different from those of SWCNT arrays. These results and analyses would provide us with a theoretical guide to the manipulation of CNT structures and thus CNT properties.

Paper B—Introduction

In this paper, catalyst particle interspacing was found to be a more accurate parameter than particle density to quantify the characteristics of densely packed catalyst particles and to affect CNT array growth. The effect of inter-particle spacing was established and systematically studied based on the investigations on catalyst particle size, density and inter-particle spacing using field emission scanning electron microscopy (FESEM) and Auger spectroscopy, and on the growth kinetics of CNT arrays using FESEM and high resolution transmission electron microscopy (HRTEM). It is anticipated that this study on the effect of inter-particle spacing may provide improved understanding and new insights on the growth mechanism of CNT arrays by CCVD. The catalyst particles disclosed here were iron oxide particles.

Paper B—Experimental Procedure

P-type Si wafers (100) with 4-in. diameter and resistivity of 1-35 Ohm-cm were used as the substrates. A buffer layer of 30 nm thick Al₂O₃ film was pulsed DC magnetron sputtered at a frequency of 20 kHz and a reverse time of 5 μs. Fe oxide catalyst films with thickness of 1 nm or 3 nm were then DC sputtered on the buffer layer at a base pressure of ˜1.0×10⁻⁷ mTorr. The sputtered substrates were cut into samples with a dimension of 8 mm×8 mm before CNT test.

Catalyst film pretreatment and CNT array growth were performed in a single-zone quartz tube furnace with an inner diameter of 5 in. The chamber was first evacuated to <0.1 Torr. After Ar purging for 1 h, the furnace temperature was ramped up to 750° C. and held for different annealing time under 200 sccm Ar and 400 sccm H₂ gas flow. 400 sccm C₂H₄ was then flowed into the system for various periods from 5 min to 2 hrs. At the end of CNT array growth, the flow of H₂ and C₂H₄ was terminated and the system was purged again with Ar during furnace cooling to below 100° C. For catalytic Fe oxide nanoparticle investigation, fast cooling (˜1 min) was employed to avoid further evolution of catalyst particles.

The morphology and height of MWCNT arrays were characterized by a JSM-6301FXVT™ field-emission scanning electron microscopy (FESEM). The size, distribution and composition of fast cooled nanoparticles were characterized by FESEM and JAMP™ 9500F Auger microprobe. Chemistry analysis of the substrate surfaces before and after CNT array growth was carried out by X-ray photoelectron spectroscopy (XPS) using a Kratos™ AXIS Ultra X-ray photoelectron spectrometer. High-resolution transmission electron microscopy (HRTEM, JEOL™ 2010 operated at 200 kV) was also performed to measure the diameter and wall numbers of CNTs. A comprehensive image analysis software, Image-Pro® Plus, was used to analyze the mean particle size, density and inter-particle spacing on the quenched surface. The detailed procedures are as follows: 1) At least ten different locations were sampled by FESEM on each specimen to produce measurements statistically significant. 2) From each location, the particle density and the distribution of particle size could be acquired by Image-Pro® Plus. 3) The results obtained in 2) were used to calculate the mean particle size and the inter-particle spacing at the location. The calculation of inter-particle spacing was made based on the mean particle size and particle density by assuming a uniform distribution of particles. 4) Finally, the mean particle size, density, inter-particle spacing and their 95% confidence intervals of the specimen were obtained by statistically analyzing the particle data from all the detected locations on the specimen.

Paper B—Results and Discussion

Morphology and Growth Kinetics of Vertically Aligned MWCNT Arrays

Highly dense, millimeter-long MWCNT arrays were deposited on both Fe oxide (1 nm) and Fe oxide (3 nm) catalyst films after 1 h CNT test without any etching agents, such as water, air or plasma, as shown in FIG. 1 of paper B. FIG. 1a of paper B is the side view of 1.1 mm long CNT arrays deposited on the Fe(3 nm) catalyst film, while FIG. 1b of paper B is that of 0.9 mm long CNT arrays deposited on the Fe(1 nm) catalyst film. The optimum pretreatment (Ar/H₂ at 750° C.) time was 60 min for FIG. 1a of paper B and 4 min for FIG. 1b of paper B. It should be noted that the breakdown of catalyst films could occur during the heating step, thus the control of heating rate is very important for the catalyst particle formation. Here, the heating rate was maintained at 37.5° C./min.

The growth kinetics of the CNT arrays formed on the Fe oxide (3 nm) and Fe oxide (1 nm) catalyst films under the corresponding optimum pretreatment conditions is shown in (a) of FIG. 12. Both curves show a parabolic-like trend with higher growth rate in the first 15 min. The initial growth rate was determined to be 74 μm/min and 68 μm/min for the Fe(3 nm) and Fe(1 nm) catalyst films, respectively. These values are higher than those of MWCNT arrays formed by CCVD (<15-60 μm/min) in other groups. The initial growth rate decreases dramatically and comes down to less than 5 μm/min after 1 hr growth as shown in the inset in (a) of FIG. 12. It is also noted that the lifetime of the Fe nanoparticles on both samples is considerably longer (more than 1 hr) than that reported in the literature. The statistic distribution of the diameter and wall number of CNTs after 30 min growth on the optimum-pretreated catalyst films is displayed in (b) and (c) of FIG. 12, respectively. It is shown that, on average, CNTs with 11.5 nm diameter and 5-7 walls were formed on 60 min-pretreated Fe oxide (3 nm) catalyst film, while CNTs with 10.3 nm diameter and 6-7 walls were formed on 4 min-pretreated Fe oxide (1 nm) catalyst film. Patole et al. has reported a substantial decrease of CNT height (from 1.2 mm to 0.38 mm) and an increase of wall number of CNTs (from 8 to 15) with increasing Fe oxide catalyst film thickness from 1 nm to 3 nm. In fact, the present work shows the opposite trend. It was found that both Fe oxide (3 nm) and Fe oxide (1 nm) catalyst films could grow millimetre-long CNT arrays; and CNT arrays grew faster and longer on the Fe oxide (3 nm) catalyst film than those on the Fe oxide (1 nm) catalyst film under the corresponding optimum pretreatment conditions, as shown in (a) of FIG. 12. The diameter and wall number of CNTs deposited on both optimum-pretreated catalyst films are also comparable, as shown in (b) and (c) of FIG. 12. As CNT array growth is highly related to catalyst particles, especially in CCVD, the observations in FIG. 12 could be understood by investigating the catalyst particles formed after different pretreatments, which is presented in the following sections.

Characterization of Catalyst Particles after Different Pretreatments

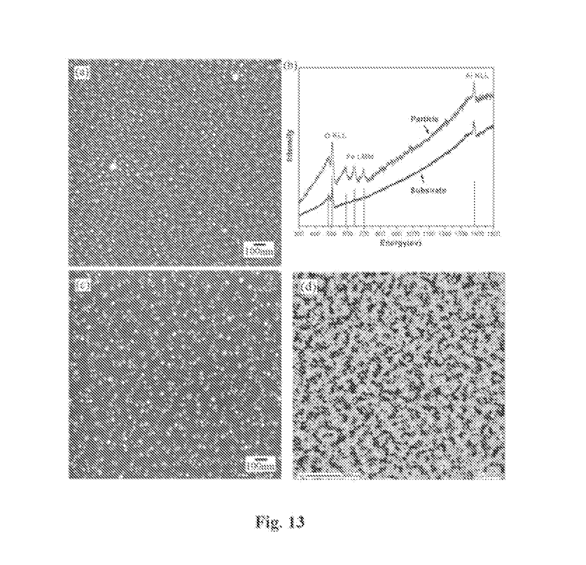

The catalyst particles after different pretreatments for Fe oxide (1 nm) and Fe oxide (3 nm) catalyst films were characterized to illustrate the effect of pretreatments on the catalyst particle formation and the effect of catalyst particles on the growth of CNT arrays. Fast cooling pretreated catalyst films from 750° C. to room temperature was performed to minimize any changes in particle size and distribution during cooling period. The particles were then examined by SEM, instead of atomic force microscopy (AFM) as used by other researchers. AFM has limited lateral resolution and couldn't give reliable particle size, shape and density. Besides, Al₂O₃ buffer layer itself also shows particle-like topography after pretreatment, which may mix up with catalyst particles in the image obtained by AFM. As shown in the SEM images in FIGS. 3 and 4 of paper B, the nanoparticles and their distributions after different pretreatments on the two catalyst films can be clearly observed. The composition of the particles on the pretreated surfaces was further examined using Auger spectroscopy. As shown in FIG. 13, strong Fe oxide peaks in the Auger profile were detected from the particles, while only Al and O peaks were detected from the substrate. Auger mapping was also performed. FIG. 13d, corresponding to FIG. 3d of paper B, is the Auger Fe oxide mapping image taken on 6 min-pretreated Fe oxide (1 nm) catalyst film. Regions in red in the paper, intermediate grey shading within light areas in FIG. 13d, have the highest Fe oxide signal, while regions in green (light shading in FIG. 13d) or blue (dark shading in FIG. 13d) have intermediate or zero Fe oxide signal, respectively. It is apparent that the pattern in FIG. 13d, FIG. 3d of paper B, is well consistent with the SEM image in FIG. 13c, FIG. 3c of paper B. Therefore, all the nanoparticles shown in the SEM images are Fe oxide catalyst particles.

The Fe oxide nanoparticle size and density observed on the SEM images were quantitatively determined using Image-Pro® Plus. After pretreatment for 4 min, the Fe oxide (1 nm) catalyst film broke apart to very small and densely packed Fe oxide nanoparticles, as shown in FIG. 3a of paper B. The mean particle density on this film was determined to be 8.23×10¹⁰(±0.25×10¹⁰)/cm², and the average particle size was 16.1±0.2 nm. However, after pretreatment for 6 min, the small and densely packed Fe oxide nanoparticles in FIG. 3a of paper B coalesced (coarsened) to a larger particle size (24.0±0.5 nm), and a much lower particle density (3.12×10¹⁰(±0.20×10¹⁰)/cm²) in FIG. 3c of paper B. The same trend was also found for the Fe oxide (3 nm) catalyst film. Relatively large (29.3±0.7 nm) but densely packed (4.89×10¹⁰(±0.12×10¹⁰/cm²) Fe oxide nanoparticles were formed after pretreatment for 60 min as shown in FIG. 4a of paper B; and the particle size was increased to 35.5±1.0 nm and particle density was reduced to 2.83×10¹⁰(±0.18×10¹⁰)/cm² after pretreatment for 70 min as shown in FIG. 4b of paper B. It should be noted that the ranges of the data determined above are 95% confidence interval of the mean. The determined particle densities are in the same order of magnitude as the CNT densities obtained by some other researchers through CCVD and WACVD processes. It is interesting to see that the kinetics of catalyst particle formation is slower for the thicker film under the same pretreatment environment, possibly because thicker film needs to absorb more energy to break apart. It is then suggested that the effect of Fe oxide catalyst film thickness on CNT array growth cannot be clarified without considering the influence of pretreatment conditions. As the pretreatment condition has a great influence on the catalyst particle formation, the observations in FIG. 12 can be attributed to the different optimum pretreatment conditions used for the two catalyst films to grow CNT arrays. The catalyst particle data and the dimensions of CNTs grown from the corresponding catalyst particles for 30 min are summarized in Table I.

Dependence of CNT Array Growth on Catalyst Particle Interspacing

Table I shows that, on the catalyst film with the same thickness, catalyst particles with smaller particle size and higher particle density could grow longer CNT arrays. However, the trend breaks down if the change of the catalyst film thickness is considered. For example, 4-min pretreated Fe oxide (1 nm) catalyst film has yielded smaller and denser catalyst particles than 60-min pretreated Fe oxide (3 nm) catalyst film, as shown in Table I; however, CNT arrays grew faster and longer on the latter film rather than on the former film, as shown in FIG. 12. The same results can also be obtained if comparing 6-min pretreated Fe oxide (1 nm) catalyst film with 70-min pretreated Fe oxide (3 nm) catalyst film. It is implied that another parameter, which can also be controlled by the pretreatment conditions, is predominant in the present case. Note that, in FIG. 4a of paper B, 60-min pretreated Fe oxide (3 nm) catalyst film has quite densely packed catalyst particles, although the value of particle density is not very high. To quantify the densely packed catalyst particles, inter-particles spacing, defined as the average distance between the perimeters of neighbouring particles, was also determined and compared with the effect of particle density.

Based on the average Fe oxide particle size and density determined, the inter-particle spacing could be calculated. The mean inter-particle spacing was found to be small for 60 min-pretreated Fe oxide (3 nm) catalyst film and 4-min pretreated Fe oxide (1 nm) catalyst film, which was 15.9±1.2 nm and 18.8±0.7 nm, respectively. However, the average inter-particle spacing for 70-min pretreated Fe oxide (3 nm) catalyst film and 6-min pretreated Fe oxide (1 nm) catalyst film in this study was a little large, 24.0±2.7 nm and 32.6±2.3 nm, respectively. The catalyst particle interspacing data are also summarized in Table I.

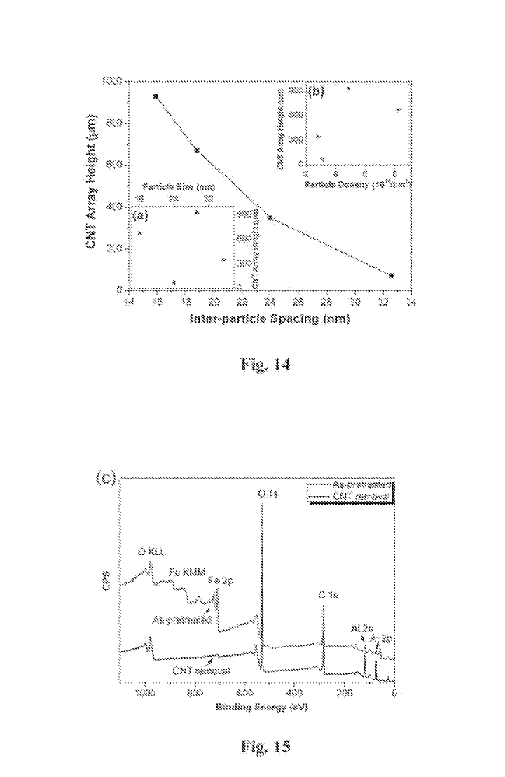

The importance of inter-particle spacing can be clearly observed by plotting the CNT array heights versus catalyst particle size, density and inter-particle spacing based on the data in Table I. As shown in the inset plots (a) and (b) in FIG. 14, although the values of catalyst particle size and density varied a lot, they did not display any meaningful correlation with CNT array height. Inter-particle spacing, on the other hand, demonstrates a strong correlation with CNT array height, that is, CNT array height decreases dramatically with increasing inter-particle spacing. It indicates that, in this investigation, the range of variation in inter-particle spacing is more significant than that in particle size and density, and thus inter-particle spacing plays a predominant role in influencing CNT array height. It should be noted that the increase of catalyst particle size is always accompanied with a decrease of particle density and an increase of inter-particle spacing for the pretreatment of the catalyst films with the same thickness. Thus, there is no difference between high particle density and small inter-particle spacing when the thickness of the catalyst films is unchanged. However, when investigating the CNT array growth on the catalyst films with different thicknesses, high particle density is not necessarily associated with a small inter-particle spacing. The decrease of particle density was also found to yield smaller inter-particle spacing (shown in Table I). As suggested by FIG. 14, inter-particle spacing is a more accurate parameter than particle density to quantify the characteristics of densely packed catalyst particles.

In addition, inter-particle spacing was found to possibly affect the diameter and wall number of CNTs. As shown in Table I, catalyst particles formed on 60-min pretreated Fe oxide (3 nm) catalyst film are larger than those on 6-min pretreated Fe oxide (1 nm) catalyst film (29.3 nm to 24.0 nm). It is generally believed that the CNT diameter can be correlated to the catalyst particle size. Surprisingly, after a 30 min's growth, the diameter and wall number of CNTs formed on the former film are much smaller, 11.5 nm and 5-7 walls, than those of CNTs formed on the latter film, 29.7 nm and 24 walls, as shown in Table I. This may be ascribed to the large difference in the inter-particle spacing between these two films (15.9 nm to 24.0 nm). More discussion of this point has been provided in the following section. Furthermore, this discussion also proves that, to affect CNT array growth, the difference in catalyst particle size in the current conditions is negligible comparing with the difference in inter-particle spacing. Thus, the effect of catalyst particle size is obscured by inter-particle spacing, which is also suggested by FIG. 14. These results point to the importance of adjusting the pretreatment conditions and the thickness of catalyst film to acquire flexible control of catalyst particle size and interspacing.

CNT Array Growth Mechanism Affected by Catalyst Particle Interspacing

In the present study, several techniques have been used to determine CNT array growth mode. In TEM observations, Fe particles were found at the tip of CNTs, as shown in FIG. 6a of paper B. To confirm the observations by TEM, SEM and XPS analysis were also performed. SEM image in FIG. 6b of paper B shows that, after removal of the grown CNT array, many craters (indicated by white arrows in FIG. 6b of paper B) rather than catalyst particles can be found. XPS spectra in FIG. 15 also demonstrate much weaker Fe peaks and stronger Al peaks on the substrate after removal of the grown CNT array than those on the as-pretreated catalyst film. Quantitative analysis of XPS spectra gives a substantial reduction in the Fe/Al atomic ratio from 5:1 on the as-pretreated catalyst film to 1:13 on the substrate after removal of the grown CNT array for Fe oxide (3 nm) catalyst films, and from 1.4:1 to 1:16 for Fe oxide (1 nm) catalyst films. The SEM and XPS analyses strongly confirm that most catalyst particles were lifted off the substrate by the grown CNT array. However, small amount of Fe left on the substrate was also detected by XPS, suggesting that the CNT array also shows a synchronous growth mode in the present study.

High resolution surface and cross section images of CNT arrays deposited on the Fe oxide (1 nm) catalyst film after 30 min CNT test are shown in FIG. 7 of paper B. The pretreatment time used for growing CNT arrays in FIGS. 7a and 7b of paper B was 4 min, while that for growing CNT arrays in FIGS. 7c and 7d of paper B was 6 min. Compared with the data in Table I, the CNT arrays grown on the small inter-particle spacing catalyst film (FIGS. 7a and 7b of paper B) are much higher than those on the large inter-particle spacing catalyst film (FIGS. 7c and 7d of paper B), which can be seen from the insets in FIG. 7a of paper B (670 nm) and FIG. 7c of paper B (70 nm), respectively. The long CNT array is densely packed with individual CNTs hardly seen on the surface in FIG. 7a of paper B. However, the short CNT array in FIG. 7c of paper B is sparsely packed with randomly grown CNTs visible on the surface. They are entangled together and form the net shape. By comparing FIG. 7b of paper B with 7d of paper B, it is also evident that most CNTs in the long CNT array (FIG. 7b of paper B), although appears wavy in shape, grew in the direction perpendicular to the substrate as indicated by the arrow; while most CNTs in the short CNT array (FIG. 7d of paper B) are not well aligned to the upward direction and demonstrate strong crossover and entanglement.

Fan et al. suggested that van der Waals interaction is one of the reasons for the aligned growth of CNTs. Consequently, when inter-particle spacing is small, catalyst particles and/or CNTs are primarily confined by their neighbours to grow in the upward direction, as shown in FIGS. 7a and 7b of paper B. However, when inter-particle spacing is large, little confinement from their surroundings promotes relatively random growth of CNTs, as shown in FIGS. 7c and 7d of paper B. Once CNTs can grow in directions quite deviated from the vertical direction, less interaction will be present among the neighbouring particles and/or CNTs for maintaining the aligned growth. As a result, although individual CNTs may still grow within the CNT array, the increase of the CNT array height on the large inter-particle spacing catalyst films stops much earlier than that on the small inter-particle spacing catalyst films. Therefore, the period of the predominant increase of CNT array height (defined as lengthening time) is short for the large inter-particle spacing catalyst films. It is proposed that inter-particle spacing affects the growth kinetics of CNT arrays by affecting their lengthening time.

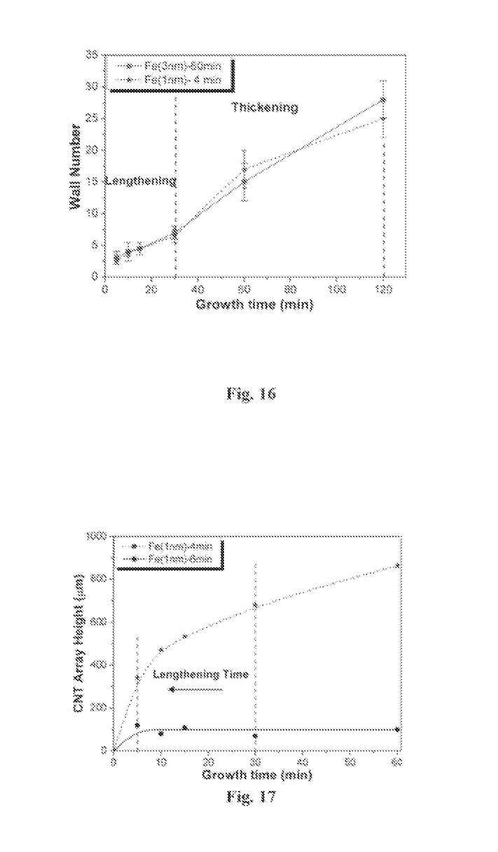

To further clarify how inter-particle spacing affects CNT array growth, HRTEM images of over 200 MWCNTs under each growth condition were taken to investigate the change of CNT wall number during CNT array growth. FIG. 16 shows some typical HRTEM images of the CNTs deposited for different growing periods. Within a 5-10 min growth period, CNTs are mostly double-walled or triple-walled. The wall number increases to 5-8 walls after 30 min growth, 12-16 walls after 1 hr growth, and goes up to 25-30 walls in the second hour growth. The change of CNT wall number with CNT array growth time was also summarized in FIG. 16. The wall number at long growth periods can still be counted, although the outer walls of CNTs are not in good graphitization, because of the deposition of graphitic-like layers. Part (a) of FIG. 12 and FIG. 16 demonstrate an obvious lengthening-thickening process during CNT array growth by CCVD. It is apparent from the diagram in FIG. 16 that the lengthening process and thickening process are competitive. In the first 30 min, CNT array growth is dominated by the lengthening process and CNT wall number increases very slowly, while after 30 min, it is dominated by the thickening process and CNT arrays grows a little in height. It is worth to note that CNTs grown on 4 min-pretreated Fe oxide (1 nm) catalyst film thickens more severely than those on 60 min-pretreated Fe oxide (3 nm) catalyst film in the region between 30 min and 1 hr, indicating a shorter lengthening time for CNT arrays grown on the former film.

The decrease of the lengthening time on the large inter-particle spacing catalyst films is also displayed in FIG. 17 by comparing the growth kinetics of CNT arrays on 4 min-pretreated and 6 min-pretreated Fe oxide (1 nm) catalyst films. For CNT array growth on 6 min-pretreated Fe oxide (1 nm) catalyst films, the lengthening process is only dominated in the initial 5 min. The HRTEM observation shows that CNTs grown for 5 min are double-walled or triple-walled. After 5 min's growth, the thickening process is predominated and the CNT wall number quickly raises up to 14 walls in 15 min, and further increases to 24 walls in 30 min, which are much larger than the wall number of CNTs grown on 4 min-pretreated Fe oxide (1 nm) catalyst films for the same growth period as shown in FIG. 16. Note that the catalyst particle size is larger on 6 min-pretreated Fe oxide (1 nm) catalyst film (24.0 nm) than that on 4 min-pretreated Fe oxide (1 nm) catalyst film (15.9 nm), but smaller than that on 60 min-pretreated Fe oxide (3 nm) catalyst film (29.3 nm); however, the substantial decrease of the lengthening time could also be obtained if comparing the growth kinetics of CNT arrays on 60 min-pretreated Fe oxide (3 nm) and 6 min-pretreated Fe oxide (1 nm) catalyst films (see part (a) of FIG. 12 and FIG. 17). It again indicates that the effect of catalyst particle size is obscured by inter-particle spacing in the current case. Therefore, these results prove the earlier proposition that inter-particle spacing affects the growth kinetics of CNT arrays by affecting their lengthening time.

FIG. 17 also suggests that inter-particle spacing could affect the diameter and wall number of CNTs because the thickening time was readjusted concurrently with the lengthening time. The delayed occurrence of a predominantly increase in CNT diameter and wall number on the small inter-particle spacing catalyst film, as shown in FIG. 17, may be resulted from the fact that the diffusion of hydrocarbon gas through the catalyst particles into the CNT array, a step necessary for pyrolytic reaction within the CNT array to produce CNT thickening, is hindered when inter-particle spacing is small. Because the effect of van der Waals interaction is a function of interaction distance and the diffusion of hydrocarbon gas must proceed through the gap between catalyst particles, inter-particle spacing, rather than particle density, is another parameter as catalyst particle size that could affect CNT array growth. It is also noted that the mechanism and dynamics of CNT deposition from the catalyst particles are important during the competitive lengthening and thickening process of CNT array growth, which requires further investigation in the future.

Paper B—Conclusions

Vertically aligned millimeter-scale carbon nanotube (CNT) arrays have been successfully deposited on both Fe oxide (3 nm)/Al₂O₃ and Fe oxide (1 nm)/Al₂O₃ catalyst films under different optimum pretreatment conditions by catalytic chemical vapor deposition. By investigating the catalyst particles before CNT array growth, it has been found that inter-particle spacing is a more accurate parameter than particle density to quantify the characteristics of densely packed catalyst particles; and adjusting the pretreatment conditions and the thickness of catalyst film could acquire a flexible control of catalyst particle size and interspacing. In addition, inter-particle spacing was found to play a significant role in influencing CNT array height, CNT diameter and wall number in the present study. Furthermore, the growth kinetics of CNT arrays grown from the two catalyst films with different pretreatment conditions shows a competitive lengthening-thickening process. Based on the studies of the growth kinetics, it has been proved that inter-particle spacing affects the CNT array height by affecting their lengthening time, and accordingly affects the diameter and wall number of CNTs because of the concurrent change in the thickening time. These results elucidate the effect of inter-particle spacing in CNT array growth and deepen our understanding of the growth mechanism of CNT arrays by CCVD.

Immaterial modifications may be made to what is disclosed here without departing from what is claimed. In the claims, the word “comprising” is used in its inclusive sense and does not exclude other elements being present. The indefinite article “a” before a claim feature does not exclude more than one of the feature being present. Each one of the individual features described here may be used in one or more embodiments and is not, by virtue only of being described here, to be construed as essential to all embodiments as defined by the claims.

TABLE I
Summary of catalyst particle data and the dimensions of CNTs
grown from the corresponding catalyst particles for 30 min.

| Fe Oxide | | Mean | Mean | Mean | CNT | | |
|---|---|---|---|---|---|---|---|
| Film | | Particle | Particle | Inter- | array | CNT | |
| Thickness on | Pretreatment | Density | Size | particle | height | Diameter | Wall |
| Fe/Al₂O₃/Si | Time (min) | (×10¹⁰/cm²) | (nm) | Spacing (nm) | (μm) | (nm) | Number |
| 3 nm | 60 | 4.89 ± 0.12 | 29.3 ± 0.7 | 15.9 ± 1.2 | 930 | 11.5 | 5-7 |
| | 70 | 2.83 ± 0.18 | 35.5 ± 1.0 | 24.0 ± 2.7 | 350 | 31.7 | 19-23 |
| 1 nm | 4 | 8.23 ± 0.25 | 16.1 ± 0.2 | 18.8 ± 0.7 | 670 | 10.3 | 6-7 |

1. A method of fabricating a carbon nanotube array, comprising growing a carbon nanotube array on an oxide catalyst layer under conditions promoting carbon nanotube growth.

2. The method of claim 1 further comprising depositing the oxide catalyst layer on a substrate used as a support prior to growing the carbon nanotube array on the oxide catalyst layer.

3. The method of claim 1 in which the oxide catalyst layer comprises a metal oxide.

4. The method of claim 3 in which the metal oxide comprises a group VIII element.

5. The method of claim 1 further comprising forming particles of metal oxide catalyst by heating the oxide catalyst layer and adding oxidation molecules for the pretreatment of the oxide catalyst layer prior to growing the CNTA on the oxide catalyst layer.

6. The method of claim 1 in which carbon nanotube (CNT) wall number and CNTA height are controlled simultaneously by changing one or more of the concentration of oxidizing molecules, carbon precursor flow rates, and the pretreatment time for the oxide catalyst layer.

7. The method of claim 1 further comprising controlling CNTA purity by controlling the CNTA growth time.

8. The method of claim 1 further comprising controlling the lengthening time of CNTA by controlling H₂ gas flow rate.

9. The method of claim 4 in which the group VIII element comprises at least one of Fe, Co, Ni, Ru, Rh, Pd, Os, Ir, or Pt.

10. The method of claim 1 in which the oxide catalyst layer comprises iron oxide.

11. The method of claim 1 in which the oxide catalyst layer is 0.5-10 nm thick.

12. The method of claim 11 in which the oxide catalyst layer comprises iron oxide.
